(19) United States
(12) Patent Application Publication
(10) Pub. No.: US 2024/0260418 A1
(43) Pub. Date: Aug. 1, 2024

(54) DISPLAY DEVICE

(71) Applicant: LG Display Co., Ltd., Seoul (KR)

(72) Inventors: SungKi KIM, Gyeonggi-do (KR); GiSang HONG, Seoul (KR); JongWon LEE, Seoul (KR); YoungWook LEE, Gyeonggi-do (KR); Jungmin KIM, Gyeonggi-do (KR); Hoseung LEE, Gyeonggi-do (KR)

(21) Appl. No.: 18/510,280

(22) Filed: Nov. 15, 2023

(30) Foreign Application Priority Data
Jan. 31, 2023 (KR) 10-2023-0013023

(51) Int. Cl. H10K 59/80; H10K 59/122; H10K 59/38

(52) U.S. Cl. CPC H10K 59/878; H10K 59/122; H10K 59/38; H10K 59/351; H10K 2102/3023

(57) ABSTRACT

Embodiments of the disclosure relate to a display device. Specifically, there may be provided a display device in which the planarization layer includes a convex portion, an inclined surface, and a slit portion to effectively extract the light from the display device to the outside to provide enhanced light efficiency, and the lower protection metal is disposed not to overlap the inclined surface to mitigate deterioration of luminance in the direction of the side viewing angle.

### CROSS-REFERENCE TO RELATED APPLICATION

This application claims priority from Korean Patent Application No. 10-2023-0013023, filed on Jan. 31, 2023, which is hereby incorporated by reference for all purposes as if fully set forth herein.

BACKGROUND

### Technical Field

Embodiments of the disclosure relate to display devices.

### Description of Related Art

Display devices that display various pieces of information on the screen are a key technology in the era of information and communication technology, and play a role to deliver a variety of information to the users.

Display devices may require excellent display quality and luminous efficiency. In particular, display devices may be required to maintain excellent display quality even when the user's viewing angle changes. In other words, display devices are required to maintain excellent display quality even at a wide viewing angle.

The display device may include light emitting elements that emit light of different colors to express various colors. However, since light emitting elements emitting light of different colors have different device characteristics, it is difficult to maintain uniform display quality even at a wide viewing angle.

### BRIEF SUMMARY

The display device may include a light emitting element that emits light. The light generated from the light emitting element included in the display device may be extracted to the outside of the display device and recognized by the user. However, part of the generated light may not be extracted to the outside. Display devices using light emitting elements may be classified into a top emission type and a bottom emission type depending on the direction in which the generated light is extracted. In the bottom emission-type display device, the light generated from the light emitting element is supposed to pass the transistor forming part where various circuit elements, such as transistors, and lines are positioned. In particular, a lower protection metal for protecting the transistor may be positioned in the transistor forming part. The luminance in the direction of the side viewing angle may be deteriorated by the lower protection metal. The disclosure is directed to a display device in which the planarization layer includes a convex portion, an inclined surface, and a slit portion to effectively extract the light from the display device to the outside to provide enhanced light efficiency, and the lower protection metal is disposed not to overlap the inclined surface to mitigate deterioration of luminance in the direction of the side viewing angle.

Embodiments of the disclosure may provide a display device in which the planarization layer includes a convex portion, an inclined surface, and a slit portion to effectively extract the light from the display device to the outside to provide enhanced light efficiency, and the lower protection metal is disposed not to overlap the inclined surface to mitigate deterioration of luminance in the direction of the side viewing angle.

Embodiments of the disclosure may provide a display device comprising a first subpixel, a substrate, a planarization layer, a first electrode, an inorganic bank, a light emitting layer, and a second electrode.

The planarization layer may be positioned on the substrate. The planarization layer may include a first convex portion, a second convex portion, a slit portion, a first inclined surface, and a second inclined surface in the first subpixel. The slit portion may be positioned between the first convex portion and the second convex portion. The first inclined surface may be positioned outside the first convex portion. The second inclined surface may be positioned outside the second convex portion.

The first electrode may be positioned on the first convex portion, the second convex portion, the slit portion, the first inclined surface, and the second inclined surface.

The inorganic bank may be positioned on the first electrode. The inorganic bank may include a first opening and a second opening. The first opening may be positioned to correspond to the first convex portion, and the second opening may be positioned to correspond to the second convex portion.

The light emitting layer may be positioned on the first electrode exposed by the first opening and the second opening and the inorganic bank.

The second electrode may be positioned on the light emitting layer. The second electrode may be positioned to overlap the first convex portion, the second convex portion, the slit portion, the first inclined surface, and the second inclined surface.

According to embodiments of the disclosure, there may be provided a display device in which the planarization layer includes a convex portion, an inclined surface, and a slit portion to effectively extract the light from the display device to the outside to provide enhanced light efficiency, and the lower protection metal is disposed not to overlap the inclined surface to mitigate deterioration of luminance in the direction of the side viewing angle.

According to embodiments of the disclosure, there may be provided a display device capable of effectively extracting light to enable low-power driving.

### DESCRIPTION OF THE SEVERAL VIEWS OF THE DRAWINGS

The above and other objects, features, and advantages of the disclosure will be more clearly understood from the following detailed description, taken in conjunction with the accompanying drawings, in which:

FIG. 1 is a view illustrating a system configuration of a display device according to embodiments of the disclosure;

FIG. 2 is a cross-sectional view of a display device and a circuit diagram of a subpixel according to embodiments of the disclosure;

FIGS. 3, 4, 5, and 6 are cross-sectional views illustrating a display device according to embodiments of the disclosure;

FIG. 7 is a cross-sectional view and a plan view of a display device according to embodiments of the disclosure; and

FIG. 8 is a cross-sectional view and a plan view of a display device according to embodiments of the disclosure.

### DETAILED DESCRIPTION

In the following description of examples or embodiments of the disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the disclosure, detailed descriptions of well-known functions and components incorporated herein will be omitted when it is determined that the description may make the subject matter in some embodiments of the disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the disclosure. Each of these terms is not used to define essence, order, sequence, or number of elements, etc., but is used merely to distinguish the corresponding element from other elements.

When it is mentioned that a first element “is connected or coupled to”, “contacts or overlaps”, etc., a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc., each other via a fourth element. Here, the second element may be included in at least one of two or more elements that “are connected or coupled to”, “contact or overlap”, etc., each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes, etc., are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Hereinafter, various embodiments of the disclosure are described in detail with reference to the accompanying drawings.

A dimension including size and a thickness of each component illustrated in the drawing are illustrated for convenience of description, and the present disclosure is not limited to the size and the thickness of the component illustrated, but it is to be noted that the relative dimensions including the relative size, location and thickness of the components illustrated in various drawings submitted herewith are part of the present disclosure.

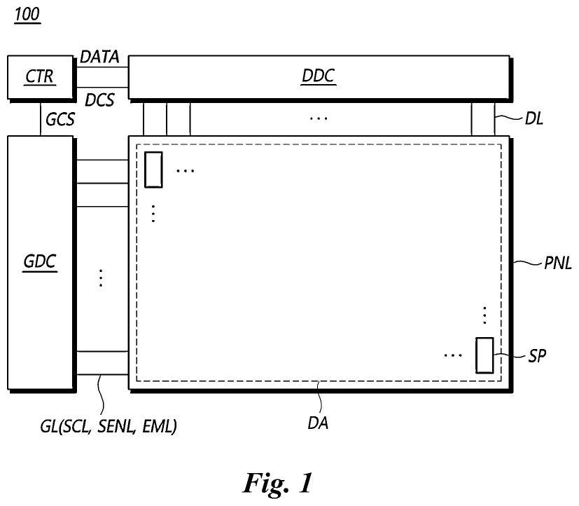

FIG. 1 is a view illustrating a system configuration of an organic light emitting display device 100 according to embodiments of the disclosure.

Referring to FIG. 1, an organic light emitting display device 100 according to the present embodiments may include a display panel PNL where a plurality of data lines DL and a plurality of gate lines GL are arranged, and a plurality of subpixels SP connected with the plurality of data lines DL and the plurality of gate lines GL are arranged in an active area A and a driving circuit for driving the display panel PNL.

From a functional point of view, the driving circuit may include a data driving circuit DDC driving the plurality of data lines DL, a gate driving circuit GDC driving the plurality of gate lines GL, and a controller CTR controlling the data driving circuit DDC and the gate driving circuit GDC.

In the display panel PNL, the plurality of data lines DL and the plurality of gate lines GL may be disposed to cross each other. For example, the plurality of data lines DL may be arranged in rows or columns, and the plurality of gate lines GL may be arranged in columns or rows. For ease of description, it is assumed below that the plurality of data lines DL are arranged in rows, and the plurality of gate lines GL are arranged in columns.

The controller CTR supplies various control signals DCS and GCS necessary for the driving operations of the data driving circuit DDC and the gate driving circuit GDC to control the data driving circuit DDC and the gate driving circuit GDC.

The controller CTR starts scanning according to a timing implemented in each frame, converts input image data input from the outside into image data DATA suited for the data signal format used in the data driving circuit DDC, outputs the image data DATA, and controls data driving at an appropriate time suited for scanning.

The controller CTR may be a timing controller used in typical display technology, or a control device that may perform other control functions as well as the functions of the timing controller.

The controller CTR may be implemented as a separate component from the data driving circuit DDC, or the controller CTR, along with the data driving circuit DDC, may be implemented as an integrated circuit.

The data driving circuit DDC receives the image data DATA from the controller CTR and supply data voltage to the plurality of data lines DL, thereby driving the plurality of data lines DL. Here, data driving circuit DDC is also referred to as a ‘source driving circuit.’

The data driving circuit DDC may include at least one source driver integrated circuit S-DIC. Each source driver integrated circuit S-DIC may include a shift register, a latch circuit, a digital-to-analog converter DAC, and an output buffer. In some cases, each source driver integrated circuit S-DIC may further include an analog-digital converter ADC.

Each source driver integrated circuit S-DIC may be connected to the bonding pad of the display panel PNL in a tape automated bonding (TAB) or chip-on-glass (COG) scheme or may be directly disposed on the display panel PNL or, in some cases, may be integrated in the display panel PNL. Each source driver integrated circuit S-DIC may also be implemented in a chip-on-film (COF) scheme to be mounted on a source-circuit film connected to the display panel PNL.

The gate driving circuit GDC sequentially drives the plurality of gate lines GL by sequentially supplying scan signals to the plurality of gate lines GL. Here, gate driving circuit GDC is also referred to as a ‘scan driving circuit.’

The gate driving circuit GDC may be connected to the bonding pad of the display panel PNL in a tape automated bonding (TAB) or chip-on-glass (COG) scheme or may be implemented in a gate-in-panel (GIP) type to be directly disposed on the display panel PNL or, in some cases, may be integrated in the display panel PNL. Further, the gate driving circuit GDC may be implemented in a chip-on-film (COF) scheme implemented with a plurality of gate driver integrated circuits G-DIC and mounted on a gate-circuit film connected to the display panel PNL.

The gate driving circuit GDC sequentially supplies scan signals of On voltage or Off voltage to the plurality of gate lines GL under the control of the controller CTR.

When a specific gate line is opened by the gate driving circuit GDC, the data driving circuit DDC converts the image data DATA received from the controller CTR into an analog data voltage and supplies the analog data voltage to the plurality of data lines DL.

The data driving circuit DDC may be positioned on only one side (e.g., the top or bottom side) of the display panel PNL and, in some cases, the data driver DDR may be positioned on each of two opposite sides (e.g., both the top and bottom sides) of the display panel PNL depending on, e.g., driving schemes or panel designs.

The gate driving circuit GDC may be positioned on only one side (e.g., the left or right side) of the display panel PNL and, in some cases, the gate driving circuit GDR may be positioned on each of two opposite sides (e.g., both the left and right sides) of the display panel PNL depending on, e.g., driving schemes or panel designs.

The plurality of gate lines GL disposed on the display panel PNL may include a plurality of scan lines SCL, a plurality of sense lines SCL, and a plurality of emission control lines EML. The scan line SCL, sense line SCL, and emission control line EML are lines for transferring different types of gate signals (scan signals, sense signals, and emission control signals) to the gate nodes of different types of transistors (scan transistors, sense transistors, and emission control transistors).

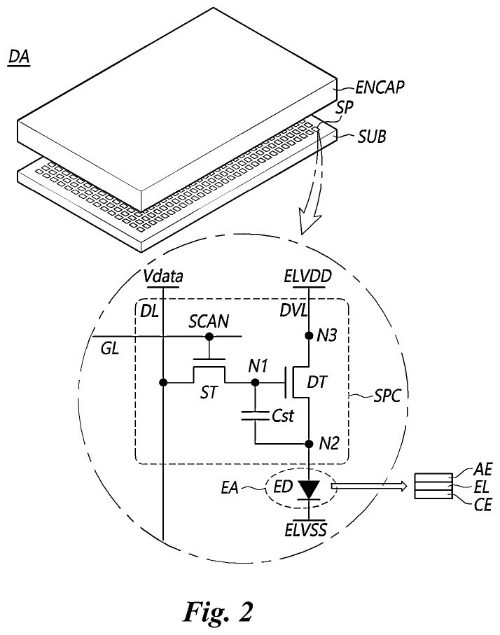

FIG. 2 illustrates a schematic cross-sectional structure of a display device and a circuit diagram of a subpixel according to embodiments of the disclosure.

Referring to FIG. 2, a plurality of subpixels SP may be disposed in the display area DA. The plurality of subpixels SP may be disposed in the normal area NA and the first optical area OA1 and the second optical area OA2 included in the display area DA.

Referring to FIG. 2, each of the plurality of subpixels SP may include a light emitting element ED and a subpixel circuit unit SPC configured to drive the light emitting element ED.

Referring to FIG. 2, the subpixel circuit unit SPC may include a driving transistor DT for driving the light emitting element ED, a scan transistor ST for transferring the data voltage Vdata to the first node N1 of the driving transistor DT, and a storage capacitor Cst for maintaining a constant voltage during one frame.

The driving transistor DT may include the first node N1 to which the data voltage may be applied, a second node N2 electrically connected with the light emitting element ED, and a third node N3 to which a driving voltage ELVDD is applied from a driving voltage line DVL. The first node N1 in the driving transistor DT may be a gate node, the second node N2 may be a source node or a drain node, and the third node N3 may be the drain node or the source node. For convenience of description, described below is an example in which the first node N1 in the driving transistor DT is a gate node, the second node N2 is a source node, and the third node N3 is a drain node.

The light emitting element ED may include an anode electrode AE, a light emitting layer EL, and a cathode electrode CE. The anode electrode AE may be a pixel electrode disposed in each subpixel SP and be electrically connected to the second node N2 of the driving transistor DT of each subpixel SP. The cathode electrode CE may be a common electrode commonly disposed in the plurality of subpixels SP, and a base voltage ELVSS may be applied thereto.

For example, the anode electrode AE may be a pixel electrode, and the cathode electrode CE may be a common electrode. Conversely, the anode electrode AE may be a common electrode, and the cathode electrode CE may be a pixel electrode. Hereinafter, for convenience of description, it is assumed that the anode electrode AE is a pixel electrode and the cathode electrode CE is a common electrode.

The light emitting element ED may have a predetermined emission area EA. The emission area EA of the light emitting element ED may be defined as an area where the anode electrode AE, the light emitting layer EL, and the cathode electrode CE overlap.

For example, the light emitting element ED may be an organic light emitting diode (OLED), an inorganic light emitting diode, or a quantum dot light emitting element. When the light emitting element ED is an organic light emitting diode, the light emitting layer EL of the light emitting element ED may include an organic light emitting layer EL including an organic material.

The scan transistor ST may be on/off controlled by a scan signal SCAN, which is a gate signal, applied via the gate line GL and be electrically connected between the first node N1 of the driving transistor DT and the data line DL.

The storage capacitor Cst may be electrically connected between the first node N1 and second node N2 of the driving transistor DT.

The subpixel circuit unit SPC may have a 2T (transistor) 1C (capacitor) structure which includes two transistors DT and ST and one capacitor Cst as shown in FIG. 2 and, in some cases, each subpixel SP may further include one or more transistors or one or more capacitors.

The capacitor Cst may be an external capacitor intentionally designed to be outside the driving transistor DT, but not a parasite capacitor (e.g., Cgs or Cgd) which is an internal capacitor that may be present between the first node N1 and the second node N2 of the driving transistor DT. Each of the driving transistor DT and the scan transistor ST may be an n-type transistor or a p-type transistor.

Since the circuit elements (particularly, the light emitting element ED implemented as an organic light emitting diode (OLED) containing an organic material) in each subpixel SP are vulnerable to external moisture or oxygen, an encapsulation layer ENCAP may be disposed to prevent penetration of external moisture or oxygen into the circuit elements (particularly, the light emitting element ED). The encapsulation layer ENCAP may be disposed to cover the light emitting elements ED.

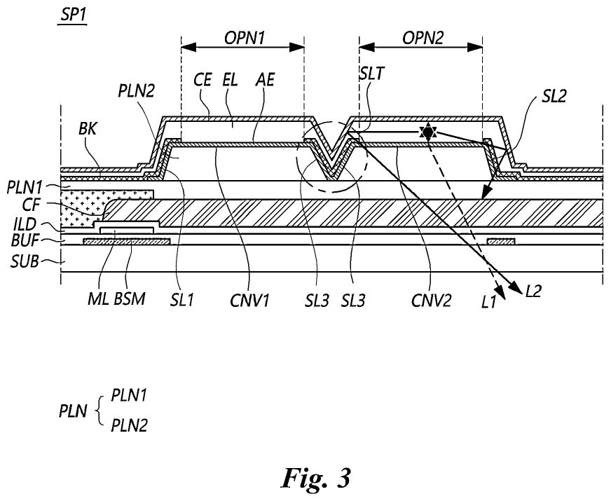

FIG. 3 is a cross-sectional view illustrating a display device according to embodiments of the disclosure. More specifically, FIG. 3 may be a cross-sectional view illustrating an area including a first subpixel SP1.

Referring to FIG. 3, a display device may include a first subpixel SP1, a substrate SUB, a planarization layer PLN, a first electrode AE, an inorganic bank BK, a light emitting layer EL, and a second electrode CE.

The first subpixel SP1 may be one of a plurality of subpixels SP positioned in the display area DA described with reference to FIGS. 1 and 2. The first subpixel SP1 may correspond to a first color. When the first subpixel SP1 corresponds to the first color, it may mean that the first subpixel SP1 emits light having the first color.

The substrate SUB may be a transistor substrate. A plurality of insulation layers, circuit elements, and signal lines constituting a transistor forming part of the display device may be positioned on the substrate SUB.

A buffer layer BUF may be positioned on the substrate SUB, and an interlayer insulation layer ILD may be positioned on the buffer layer BUF.

Although not shown in FIG. 3, various circuit elements such as transistors and signal lines may be positioned on the buffer layer BUF. A circuit element such as a transistor or the like or a metal layer ML constituting a signal line may be positioned on the buffer layer BUF. A lower protection metal BSM positioned under the transistor to overlap the transistor and capable of protecting the active layer of the transistor may be positioned on the substrate SUB. The lower protection metal BSM positioned without overlapping the transistor may constitute various circuit elements or signal lines.

The lower protection metal BSM may be positioned not to overlap the first opening OPN1 and the second opening OPN2. When the lower protection metal BSM is positioned not to overlap the first opening OPN1 and the second opening OPN2, it may mean that the lower protection metal BSM is positioned not to vertically overlap the first opening OPN1 and the second opening OPN2 on the vertical cross section of the display device. As the lower protection metal BSM is positioned not to overlap the first opening OPN1 and the second opening OPN2, the display device may have better efficiency and luminance.

A planarization layer PLN may be positioned on the substrate SUB. The planarization layer PLN may be a single layer or a multilayer structure. For example, the planarization layer PLN may include a first planarization layer PLN1 and a second planarization layer PLN2 positioned on the first planarization layer PLN1.

The planarization layer PLN may include a first convex portion CNV1, a second convex portion CNV2, a slit portion SLT, a first inclined surface SL1, and a second inclined surface SL2 in the first subpixel SP1.

The first convex portion CNV1 is a portion in which the planarization layer PLN protrudes convexly from the substrate SUB, and may mean any one convex portion included in the first subpixel SP1 by the planarization layer PLN. More specifically, the first convex portion CNV1 may mean any one plane protruding from the planarization layer PLN in the first subpixel SP1.

The second convex portion CNV2 is a portion in which the planarization layer PLN protrudes convexly from the substrate SUB, and may mean one convex portion included in the first subpixel SP1 by the planarization layer PLN and different from the first convex portion CNV1. More specifically, the second convex portion CNV2 may refer to any one plane protruding from the planarization layer PLN in the first subpixel SP1 and spaced apart from the first convex portion CNV1.

The slit portion SLT may be positioned between the first convex portion CNV1 and the second convex portion CNV2. The slit portion SLT may refer to a portion of the planarization layer PLN recessed between the first convex portion CNV1 and the second convex portion CNV2 such that the first convex portion CNV1 and the second convex portion CNV2 are distinguished from each other.

The slit portion SLT may include a third inclined surface SL3. The third inclined surface SL3 may have an angle at which part L2 of the light L1 and L2 generated from the light emitting layer EL may be extracted to the outside of the display device. For example, the third inclined surface SL3 may have an angle at which the first convex portion CNV1 and the second convex portion CNV2 become thinner away from the substrate SUB. The angle of the third inclined surface SL3 described above may be defined as an angle formed by the first convex portion CNV1 or the second convex portion CNV2 and the third inclined surface SL3. As the slit portion SLT includes the third inclined surface, the first subpixel SP1 may have a so-called internal mirror structure, and thus the display device may have excellent light efficiency.

The third inclined surface SL3 may be positioned between the first opening OPN1 and the second opening OPN2. As the third inclined surface SL3 is positioned between the first opening OPN1 and the second opening OPN2, the second electrode CE positioned on the third inclined surface SL3 may extract part of the light emitted through the first opening OPN1 and the second opening OPN2 to the outside of the display device.

The first inclined surface SL1 may be positioned outside the first convex portion CNV1. The first inclined surface SL1 may be positioned to surround a portion of the first convex portion CNV1. For example, the first inclined surface SL1 and the slit portion SLT may be positioned to surround the entire first convex portion CNV1. As the first inclined surface SL1 is positioned as described above, the second electrode CE positioned on the first inclined surface SL1 may effectively extract light generated from the light emitting layer EL to the outside of the display device.

The second inclined surface SL2 may be positioned outside the second convex portion CNV2. The second inclined surface SL2 may be positioned to surround a portion of the second convex portion CNV2. For example, the second inclined surface SL2 and the slit portion SLT may be positioned to surround the entire second convex portion CNV2. As the second inclined surface SL2 is positioned as described above, the second electrode CE positioned on the second inclined surface SL2 may effectively extract light generated from the light emitting layer EL to the outside of the display device.

In the disclosure, a structure that reflects light from an inclined surface positioned outside the opening and extracts light to the outside of the display device according to embodiments of the disclosure may be referred to as a side mirror structure. Further, in embodiments of the disclosure, a structure in which the slit portion described above is positioned between the plurality of openings and the inclined surface of the slit portion reflects light to extract light to the outside of the display device may be referred to as a divided side mirror structure.

The first electrode AE may be positioned on the planarization layer PLN. The first electrode AE may be an anode electrode. Further, the first electrode AE may be a transparent electrode.

The first electrode AE may be positioned on the first convex portion CNV1, the second convex portion CNV2, the slit portion SLT, the first inclined surface SL1, and the second inclined surface SL2. In this example, the area in which the first electrode AE is positioned may be divided by the slit portion SLT.

The inorganic bank BK may include a first opening OPN1 and a second opening OPN2. The inorganic bank BK may include a plurality of holes. Each of the first opening OPN1 and the second opening OPN2 may be one of a plurality of holes included in the inorganic bank BK and may be a hole included in the first subpixel SP1.

The first opening OPN1 may be positioned to correspond to the first convex portion CNV1. In this example, the first opening OPN1 may be positioned to overlap the first convex portion CNV1.

The second opening OPN2 may be positioned to correspond to the second convex portion CNV2. In this example, the second opening OPN2 may be positioned to overlap the second convex portion CNV2.

The inorganic bank BK may be positioned on the first electrode AE. As the inorganic bank BK is positioned on the first electrode AE, a portion of the first electrode AE may be exposed by the first opening OPN1 and the second opening OPN2.

The inorganic bank BK may be positioned to overlap a portion of the first convex portion CNV1 and may be positioned to overlap a portion of the second convex portion CNV2. In other words, the inorganic bank BK may be positioned to overlap the first inclined surface SL1, the second inclined surface SL2, and the third inclined surface SL3, with a slight margin overlapping the first convex portion CNV1 and the second convex portion CNV2. The inorganic bank BK may be positioned on a portion of the upper surfaces of the first convex portion CNV1 and the second convex portion CNV2, and may extend toward the first inclined surface SL1 and the second inclined surface SL2 and may be positioned on the upper portion of the second planarization layer PLN2. The inorganic bank BK disposed in the slit portion SLT is positioned along the third inclined surface SL3 from a portion of the upper surface of the first convex portion CNV1 and continuously extends to a portion of the upper surface of the second convex portion CNV2. When the inorganic bank BK is positioned to overlap a portion of the first convex portion CNV1 and a portion of the second convex portion CNV2, deterioration of the light emitting element due to a current imbalance caused by a thickness deviation of the light emitting layer EL may be reduced. Further, in order to minimize the non-emission area due to the slit portion SLT, the width of the inorganic bank BK disposed on the third inclined surface SL3, i.e., the width of the slit portion SLT, is smaller than the width of the inorganic bank BK disposed on the first inclined surface SL1 and the second inclined surface SL2. The width of the slit portion SLT in contact with the first planarization layer PLN1 may be the same as or smaller than the width of the third inclined surface SL3.

The material of the inorganic bank BK is not particularly limited, and may be an inorganic material that may be used as the bank BK or the pixel defining film. For example, the inorganic bank BK may include silicon oxide SiO2. When the display device includes the inorganic bank BK, the bank may be formed thinner than the bank including the organic material, and thus a shift of the wavelength of light emitted through the inorganic bank BK may be reduced. When the first electrode AE is formed of a triple layer, i.e., ITO/Ag/ITO, the Ag layer of the first electrode AE may be damaged by dry etch gas penetration during a dry etch process of forming or patterning the inorganic bank BK. However, even if the inorganic bank BK is formed on the first electrode AE formed of the ITO single layer as in the embodiment of the disclosure, no or minimized damage may be done.

The light emitting layer EL may be positioned on the first electrode AE exposed by the first opening OPN1 and the second opening OPN2. In this example, the light emitting layer EL may contact a portion of the first electrode AE exposed by the first opening OPN1 and a portion of the first electrode AE exposed by the second opening OPN2. Also, the light emitting layer EL may be positioned on the inorganic bank BK.

The second electrode CE may be positioned on the light emitting layer EL. The second electrode CE may be positioned to overlap the first convex portion CNV1, the second convex portion CNV2, the slit portion SLT, the first inclined surface SL1, and the second inclined surface SL2. In this example, the second electrode CE may be a reflective electrode. Since the second electrode CE is positioned to overlap the inclined surfaces SL1 and SL2, the second electrode CE may reflect the light generated from the light emitting layer EL, more effectively extracting the light to the outside of the display device. The second electrode CE may be commonly deposited throughout the display area.

The display device may further include a color filter CF. The color filter CF may be positioned between the substrate SUB and the planarization layer PLN. Since the display device includes the color filter CF, the display device may have better color reproducibility.

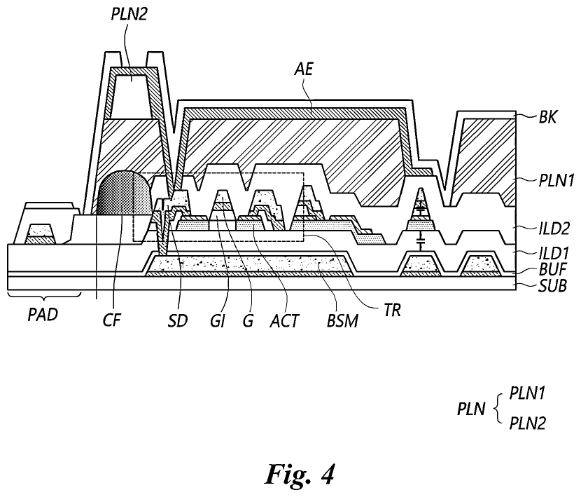

FIG. 4 is a cross-sectional view illustrating a display device according to embodiments of the disclosure. More specifically, FIG. 4 is a cross-sectional view of a display area, a non-display area, and a pad portion PAD of a display device according to embodiments of the disclosure. Unless otherwise described, the matters regarding the display device illustrated in FIG. 4 may be the same as the corresponding matters of the display device described above with reference to FIG. 3.

Referring to FIG. 4, the first interlayer insulation layer ILD1 may be positioned on the buffer layer BUF, and the second interlayer insulation layer ILD2 may be positioned on the first interlayer insulation layer ILD1.

The display device may include a transistor TR and a lower protection metal BSM.

The transistor TR may be positioned between the substrate SUB and the planarization layer PLN. The transistor TR may be positioned on the buffer layer BUF. The transistor TR may include a source-drain electrode SD, a gate electrode G, and an active layer ACT. The gate insulation layer GI may be positioned between the active layer ACT and the gate electrode G.

The lower protection metal BSM may be positioned on the substrate SUB. The lower protection metal BSM may be positioned under the transistor TR. The lower protection metal BSM may be positioned to overlap the transistor TR. More specifically, the lower protection metal BSM may be positioned to overlap the active layer ACT of the transistor TR. As the lower protection metal BSM is positioned to overlap the transistor TR, it is possible to prevent the active layer ACT from being deteriorated by light outside the display device.

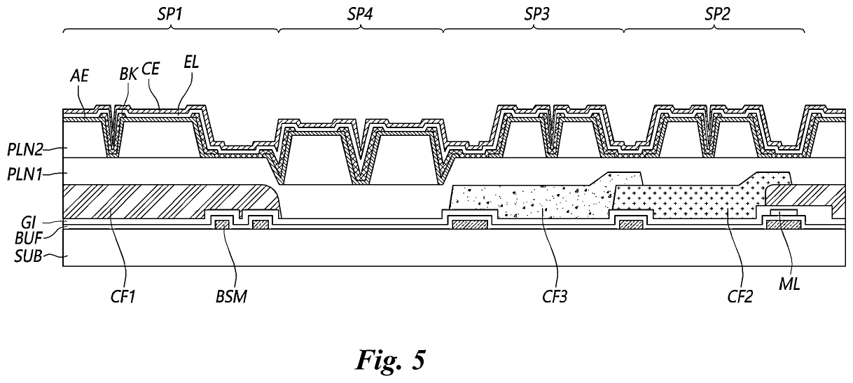

FIG. 5 illustrates a display device according to embodiments of the disclosure. More specifically, FIG. 5 is a cross-sectional view of portions of a first subpixel SP1, a second subpixel SP2, a third subpixel SP3, and a fourth subpixel SP4 positioned adjacent to each other. Unless otherwise described, the matters regarding the display device illustrated in FIG. 5 may be the same as the corresponding matters of the display device described above with reference to FIG. 3.

Referring to FIG. 5, the first subpixel SP1, the second subpixel SP2, the third subpixel SP3, and the fourth subpixel SP4 may correspond to different colors. For example, the first subpixel SP1 may correspond to red, the second subpixel SP2 may correspond to green, the third subpixel SP3 may correspond to blue, and the fourth subpixel SP4 may correspond to white. In this example, the light emitting layer EL may emit white light from all of the first subpixel SP1, the second subpixel SP2, the third subpixel SP3, and the fourth subpixel SP4. A first color filter CF1 may be positioned in the first subpixel SP1, a second color filter CF2 may be positioned in the second subpixel SP2, and a third color filter may be positioned in the third subpixel SP3. A color filter may not be positioned in the fourth subpixel SP4. In this example, the first color filter CF1 may correspond to red, the second color filter CF2 may correspond to green, and the third color filter CF3 may correspond to blue. In other words, the first color filter CF1 may convert the white light formed in the light emitting layer EL into red, the second color filter CF2 may convert the white light formed in the light emitting layer EL into green, and the third color filter CF3 may convert the white light formed in the light emitting layer EL into blue.

The first subpixel SP1, the second subpixel SP2, the third subpixel SP3, and the fourth subpixel SP4 may all have the side mirror structure described above. Further, the first subpixel SP1, the second subpixel SP2, the third subpixel SP3, and the fourth subpixel SP4 may all have the divided side mirror structure described above. When all subpixels corresponding to different colors have a divided side mirror structure, the display device may have better efficiency.

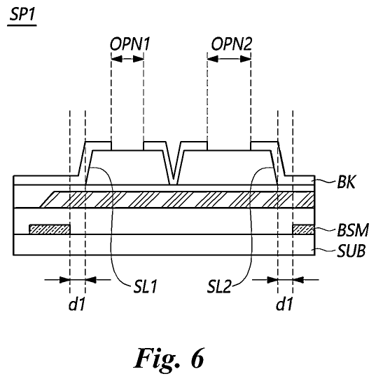

FIG. 6 is a cross-sectional view illustrating a display device according to embodiments of the disclosure. More specifically, FIG. 6 is a cross-sectional view of a first subpixel portion of a display device. Unless otherwise described, the matters regarding the display device illustrated in FIG. 6 may be the same as the corresponding matters of the display device described above with reference to FIG. 3.

Referring to FIG. 6, the lower protection metal BSM may be positioned not to overlap the first opening OPN1 and the second opening OPN2. Further, the lower protection metal BSM may be positioned not to overlap the first inclined surface SL1 and the second inclined surface SL2. In FIG. 6, the lower protection metal BSM may be positioned to be spaced apart from the first inclined surface SL1 by a first distance d1, and may be positioned to be spaced apart from the second inclined surface SL2 by a second distance d2. Since the lower protection metal BSM is positioned not to overlap the first inclined surface SL1 and the second inclined surface SL2, it is possible to reduce the luminance of the display device in the direction of the side viewing angle. Further, when the lower protection metal BSM is positioned to be spaced apart from the first inclined surface SL1 and the second inclined surface SL2 by a specific distance, light extracted by the side mirror structure formed by the inclined surface may be prevented from being blocked by the lower protection metal BSM, and thus luminance deterioration in the direction of the side viewing angle may further be mitigated.

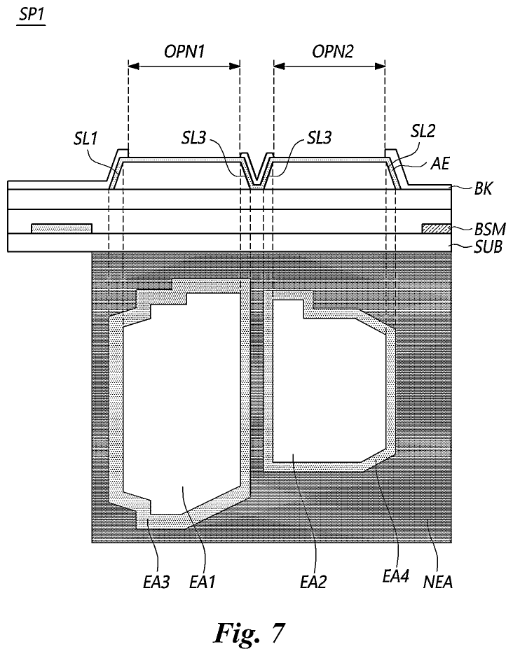

FIG. 7 is a cross-sectional view and a plan view of a display device according to embodiments of the disclosure. More specifically, FIG. 7 is a cross-sectional view of a first subpixel SP1 of a display device and a plan view when the first subpixel SP1 emits light. Unless otherwise described, the matters regarding the display device illustrated in FIG. 7 may be the same as the corresponding matters of the display device described above with reference to FIG. 6.

Referring to FIG. 7, the display device may include a first emission area EA1, a second emission area EA2, a third emission area EA3, a fourth emission area EA4, and a non-emission area NEA. Since the first emission area EA1, the second emission area EA2, the third emission area EA3, and the fourth emission area EA4 are positioned in the first subpixel SP1, the first emission area EA1, the second emission area EA2, the third emission area EA3, and the fourth emission area EA4 may emit light of the same or similar colors. Further, to enhance the left and right viewing angles, at least one slit portion SLT crossing the first subpixel SP1 in the long side direction may be formed. Accordingly, the first subpixel SP1 divided by at least one slit portion SLT may have a first opening OPN1 and a second opening OPN2 having different sizes or asymmetric areas. As illustrated in FIG. 7, the respective widths of the first opening OPN1 and the second opening OPN2 may be the same in the middle area of the first subpixel, but may be different in the upper area or the lower area.

The first emission area EA1 and the second emission area EA2 may be positioned in the first subpixel SP1. The first emission area EA1 and the second emission area EA2 may be main emission areas of the first subpixel SP1.

The third emission area EA3 may be positioned outside the first emission area EA1. The fourth emission area EA4 may be positioned outside the second emission area EA2. The third emission area EA3 and the fourth emission area EA4 may be auxiliary emission areas of the first subpixel SP1.

The first emission area EA1 may be positioned to correspond to the first opening OPN1, and the second emission area EA2 may be positioned to correspond to the second opening OPN2. The third emission area EA3 may be positioned to correspond to the first inclined surface SL1 and the third inclined surface SL3, and the fourth emission area EA4 may be positioned to correspond to the second inclined surface SL2 and the third inclined surface SL3.

The first emission area EA1 and the second emission area EA2 may be emission areas formed as the light generated from the light emitting layer EL is emitted to the outside of the display device without being reflected from the second electrode positioned to overlap the inclined surface. The third emission area EA3 may be an emission area formed as the light generated by the light emitting layer EL is reflected by the second electrode and then emitted to the outside of the display device. The fourth emission area EA4 may be an emission area formed as the light generated from the light emitting layer EL is reflected by the second electrode positioned to overlap the second inclined surface SL1 or the third inclined surface SL3 and then emitted to the outside of the display device.

The first emission area EA1 and the third emission area EA3 may differ from each other in one or more of color coordinates and luminance. This is because the optical path of the light reaching the first emission area EA1 and the optical path of the light reaching the third emission area EA3 differ in terms of whether the light passes through the inorganic bank BK.

The second emission area EA2 and the fourth emission area EA4 may differ from each other in one or more of color coordinates and luminance. This is because the optical path of the light reaching the second emission area EA2 and the optical path of the light reaching the fourth emission area EA4 differ in terms of whether the light passes through the inorganic bank BK.

The third emission area EA3 may be continuously positioned in contact with the first emission area EA1. Further, the fourth emission area EA4 may be continuously positioned in contact with the second emission area EA2. In the display device according to embodiments of the disclosure, since the side mirror structure includes the inorganic bank BK which is thin as compared with the organic bank, and the lower protection metal BSM is positioned not to overlap the openings OPN1 and OPN2 and the inclined surfaces SLO1 and SLO2, the third emission area EA3 and the fourth emission area EA4, which are auxiliary emission areas, may be continuously positioned in contact with the first emission area EA1 and the second emission area EA2, which are main emission areas, rather than being spaced apart from the first emission area EA1 and the second emission area EA2.

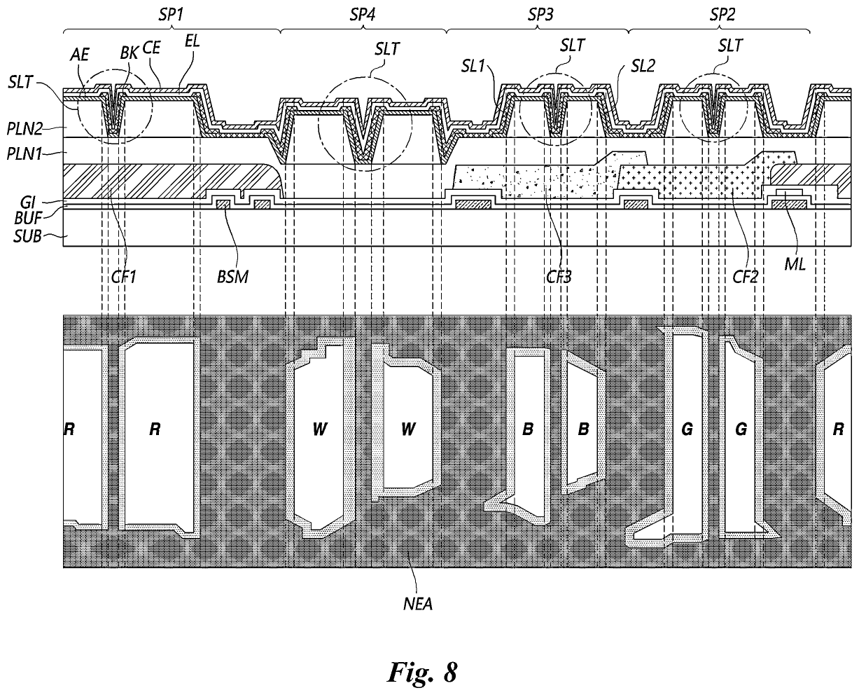

FIG. 8 is a cross-sectional view and a plan view of a display device according to embodiments of the disclosure.

Referring to FIG. 8, the inorganic bank BK may overlap one color filter CF1, CF2, or CF3 in the slit portion SLT. In other words, the inorganic bank BK may be positioned to overlap one of the color filters CF1, CF2, and CF3 in the slit portion SLT of the first subpixel SP1, the second subpixel SP2, and the third subpixel SP3. Since the color filter is not positioned in the fourth subpixel SP4 corresponding to white, the inorganic bank BK may not overlap the color filter in the slit portion SLT of the fourth subpixel SP4.

In the first subpixel SP1, the second subpixel SP3, the third subpixel SP3, and the fourth subpixel SP4, the inorganic bank BK of the slit portion SLT may not overlap the lower line. In other words, the inorganic bank BK of the slit portion SLT may be positioned not to overlap the lower protection metal BSM and the metal layer ML which are the lower lines.

The inorganic bank BK positioned on the first inclined surface SL1 and the second inclined surface SL2 may be positioned to overlap the lower line. Further, the inorganic bank BK positioned on the first inclined surface SL2 and the second inclined surface SL2 may be positioned to overlap the at least one color filter CF1, CF2, or CF3.

Embodiments of the disclosure described above are briefly described below.

A display device 100 may comprise a first subpixel SP1, a substrate SUB, a planarization layer PLN, a first electrode AE, a light emitting layer EL, and a second electrode CE.

A planarization layer PLN may be positioned on the substrate SUB. The planarization layer PLN may include a first convex portion CNV1, a second convex portion CNV2, a slit portion SLT, a first inclined surface SL1, and a second inclined surface SL2 in the first subpixel SP1. The slit portion SLT may be positioned between the first convex portion CNV1 and the second convex portion CNV2. The first inclined surface SL1 may be positioned outside the first convex portion CNV1. The second inclined surface SL2 may be positioned outside the second convex portion CNV2.

The first electrode AE may be positioned on the first convex portion CNV1, the second convex portion CNV2, the slit portion SLT, the first inclined surface SL1, and the second inclined surface SL2.

The inorganic bank BK may be positioned on the first electrode AE. The inorganic bank BK may include a first opening OPN1 and a second opening OPN2. The first opening OPN1 may be positioned to correspond to the first convex portion CNV1. The second opening OPN2 may be positioned to correspond to the second convex portion CNV2.

The light emitting layer EL may be positioned on the first electrode CE exposed by the first opening OPN1 and the second opening OPN2. Also, the light emitting layer EL may be positioned on the inorganic bank BK.

The second electrode CE may be positioned on the light emitting layer EL. Further, the second electrode CE may be positioned to overlap the first convex portion CNV1, the second convex portion CNV2, the slit portion SLT, the first inclined surface SL1, and the second inclined surface SL2.

The first inclined surface SL1 may be positioned outside the first opening OPN1. The second inclined surface SL2 may be positioned outside the second opening OPN2.

The slit portion SLT may include a third inclined surface SL3.

The third inclined surface SL3 may be positioned between the first opening OPN1 and the second opening OPN2.

The inorganic bank BK may be positioned to overlap the third inclined surface SL3.

The inorganic bank BK may be positioned to overlap the first inclined surface SL1 and the second inclined surface SL2.

The first electrode AE may be a transparent electrode, and the second electrode CE may be a reflective electrode.

The display device 100 may include a color filter CF. The color filter CF may be positioned between the substrate SUB and the planarization layer PLN.

The display device 100 may include a transistor TR and a lower protection metal BSM. The transistor TR may be positioned between the substrate SUB and the planarization layer PLN. The lower protection metal BSM may be positioned on the substrate SUB and may be positioned under the transistor TR. The lower protection metal BSM may be positioned to overlap the transistor TR.

The lower protection metal BSM may be positioned not to overlap the first opening OPN1 and the second opening OPN2. Further, the lower protection metal BSM may be positioned not to overlap the first inclined surface SL1 and the second inclined surface SL2.

The display device may include a first emission area EA1, a second emission area EA2, a third emission area EA3, a fourth emission area EA4, and a non-emission area NEA. The first emission area EA1 and the second emission area EA2 may be positioned in the first subpixel SP1.

The third emission area EA3 may be positioned outside the first emission area EA1. The fourth emission area EA4 may be positioned outside the second emission area EA2.

The first emission area EA1 may be positioned to correspond to the first opening OPN1, and the second emission area EA2 may be positioned to correspond to the second opening OPN2. The third emission area EA3 may be positioned to correspond to the first inclined surface SL1 and the third inclined surface SL3, and the fourth emission area EA4 may be positioned to correspond to the second inclined surface SL2 and the third inclined surface SL3.

The third emission area EA3 may be continuously positioned in contact with the first emission area EA1. Further, the fourth emission area EA4 may be continuously positioned in contact with the second emission area EA2.

The above description has been presented to enable any person skilled in the art to make and use the technical idea of the disclosure, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the disclosure. The above description and the accompanying drawings provide an example of the technical idea of the disclosure for illustrative purposes only. That is, the disclosed embodiments are intended to illustrate the scope of the technical idea of the disclosure.

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a first subpixel;
a substrate;
a planarization layer on the substrate and including a first convex portion, a second convex portion, a slit portion between the first convex portion and the second convex portion, a first inclined surface outside the first convex portion, and a second inclined surface outside the second convex portion in the first subpixel;
a first electrode on the first convex portion, the second convex portion, the slit portion, the first inclined surface, and the second inclined surface;
an inorganic bank on the first electrode and including a first opening corresponding to the first convex portion and a second opening corresponding to the second convex portion;
a light emitting layer on the first electrode exposed by the first opening and the second opening and the inorganic bank; and
a second electrode on the light emitting layer and overlapping the first convex portion, the second convex portion, the slit portion, the first inclined surface, and the second inclined surface.

2. The display device of claim 1, wherein the first inclined surface is outside the first opening, and the second inclined surface is outside the second opening.

3. The display device of claim 1, wherein the slit portion includes a third inclined surface.

4. The display device of claim 3, wherein the third inclined surface is between the first opening and the second opening.

5. The display device of claim 3, wherein the inorganic bank is overlapping the third inclined surface.

6. The display device of claim 1, wherein the inorganic bank is overlapping the first inclined surface and the second inclined surface.

7. The display device of claim 1, wherein the first electrode is a transparent electrode, and wherein the second electrode is a reflective electrode.

8. The display device of claim 1, further comprising a color filter between the substrate and the planarization layer.

9. The display device of claim 1, further comprising:
a transistor between the substrate and the planarization layer; and
a lower protection metal on the substrate, under the transistor, and overlapping the transistor.

10. The display device of claim 9, wherein the lower protection metal is not overlapping the first opening and the second opening.

11. The display device of claim 10, wherein the lower protection metal is not overlapping the first inclined surface and the second inclined surface.

12. The display device of claim 1, further comprising:
a first emission area in the first subpixel;
a second emission area in the first subpixel;
a third emission area outside the first emission area;
a fourth emission area outside the second emission area; and
a non-emission area.

13. The display device of claim 12, wherein the first emission area corresponds to the first opening, the second emission area corresponds to the second opening, the third emission area corresponds to the first inclined surface and the third inclined surface, and the fourth emission area corresponds to the second inclined surface and the third inclined surface.

14. The display device of claim 12, wherein the third emission area is continuously in contact with the first emission area, and the fourth emission area is continuously in contact with the second emission area.

15. A device, comprising:
a first subpixel including:
a first color filter layer;
a second subpixel including:
a second color filter layer;
a first planarization layer on the first and second subpixel, the first planarization layer including:
a first slit that overlaps the first color filter layer; and
a second slit that is between the first color filter layer and the second color filter layer.

16. The device of claim 15 comprising a second planarization layer that is between the first color filter layer and the first planarization layer, the second planarization layer is between the second color filter layer and the first planarization layer.

17. The device of claim 16 comprising a substrate, the first subpixel and the second subpixel being on the substrate, a bottom of the first slit being further from the substrate than a bottom of the second slit.

18. A device, comprising:
a substrate;
a first color filter layer on the substrate;
a second color filter layer on the substrate;
a third color filter layer on the substrate;
a first planarization layer on the first, second, and third color filter layers, the first planarization layer including:
a first slit aligned with the first color filter layer;
a second slit aligned with the second color filter layer;
a third slit aligned with the third color filter layer; and
a fourth slit between the first and third color filter layers.

19. The device of claim 18 comprising:
an anode layer in the first slit;
a bank layer on the anode layer in the first slit;
a light emitting layer on the bank layer in the first slit; and
a cathode layer on the light emitting layer in the first slit.

20. The device of claim 19 wherein a bottom of the first slit is further from the substrate than a bottom of the fourth trench.
